(19) United States
(12) Patent Application Publication
(10) Pub. No.: US 2013/0191052 A1
(43) Pub. Date: Jul. 25, 2013

(54) REAL-TIME SIMULATION OF POWER GRID DISRUPTION

(71) Applicants: Steven J. Fernandez, Knoxville, TN (US); Mallikarjun Shankar, Knoxville, TN (US); James J. Nutaro, Oak Ridge, TN (US); Yilu Liu, Knoxville, TN (US); Aleksandar D. Dimitrovski, Knoxville, TN (US); Olufemi A. Omitaomu, Knoxville, TN (US); Christopher S. Groer, Knoxville, TN (US); Kyle L. Spafford, Knoxville, TN (US); Ranga R. Vatsavai, Knoxville, TN (US)

(72) Inventors: Steven J. Fernandez, Knoxville, TN (US); Mallikarjun Shankar, Knoxville, TN (US); James J. Nutaro, Oak Ridge, TN (US); Yilu Liu, Knoxville, TN (US); Aleksandar D. Dimitrovski, Knoxville, TN (US); Olufemi A. Omitaomu, Knoxville, TN (US); Christopher S. Groer, Knoxville, TN (US); Kyle L. Spafford, Knoxville, TN (US); Ranga R. Vatsavai, Knoxville, TN (US)

(21) Appl. No.: 13/747,779

(22) Filed: Jan. 23, 2013

Related U.S. Application Data
(60) Provisional application No. 61/589,419, filed on Jan. 23, 2012.

(51) Int. Cl. G06F 17/00; G01R 21/00

(52) U.S. Cl. CPC G06F 17/00; G01R 21/00
USPC 702/60

(57) ABSTRACT

A method and system for monitoring the electric grid and predicting failures and/or other issues. Streams of data about a power grid are received from a plurality of remote power grid sensors and converted into a univariate time sequence. Anomaly patterns are identified in the univariate time sequence and analyzed or simulated to predict the power grid disruption. The anomaly patterns are compared to power disruption contingencies stored in a database to simulate and/or predict the present or future power disruption represented by the anomaly pattern.

### CROSS REFERENCE TO RELATED APPLICATION

This application claims the benefit of U.S. Provisional Patent Application Serial No. 61/589,419, filed on 23 Jan. 2012. The co-pending Provisional Application is hereby incorporated by reference herein in its entirety and is made a part hereof, including but not limited to those portions which specifically appear hereinafter.

### GOVERNMENT RIGHTS

This invention was made with government support under Contract No. DE-AC05-00OR22725 awarded by the U.S. Department of Energy. The government has certain rights in the invention.

### FIELD OF THE INVENTION

The present invention relates to a computer-implemented method, and software for executing the method, for understanding and responding to the status, both observed and predicted, of the electric grid, and more particularly to monitoring the electric grid and predicting failures and/or other issues.

### BACKGROUND OF THE INVENTION

The U.S. electric power system includes multiple distinct interconnections of generators, high voltage transmission systems, and local distribution systems that maintain a continuous balance between generation and load with impressive levels of efficiency and reliability. This critical infrastructure has served the nation remarkably well, but is likely to see more changes over the next decade than it has seen over the past century. In particular, the widespread deployment of renewable generation, smart-grid controls, energy storage, and new conducting materials will require fundamental changes in grid planning and the way the power grid is run. The multiple distinct interconnections could be re-drawn or weakened and components separated widely geographically will be closely coupled. In addition, rapid re-configuration in response to disruption signals will be likely over the next eight years.

These changes provide the foundation for striking improvements in system design and operation for greater system performance, efficiency, and cost effectiveness. They will enable new approaches to system optimization and control. National policy objectives to increase clean power generation with renewable resources will add significant complexity, requiring new classes of stochastic forecasting and control processes for the grid. Advances in end-use efficiency will increase the complexity of end-use models necessary to accurately forecast electricity demand. Greater use of market signals will create complex new patterns of consumption. As a result of these advances, significant opportunities for improving the effectiveness and efficiency of our energy system will present themselves. However, modeling these changes requires new techniques because the grid components are now more closely coupled in their responses (e.g., separating into microgrids will have decreasing validity). Complexity of this coupling will require the next generation of scientific computing resources to solve these cases in realistic time.

The Department of Energy (DOE) Office of Electricity has a goal of understanding and responding to the status (observed and predicted) of the electric grid. DOE Office of Science has a goal of applying the next generation of scientific computing to address significant power grid challenges. A consensus is developing within the Department of Energy that the qualitatively new challenge that exascale applications can contribute to support the evolution of the 21^{st} Century power grid under these changing conditions is the real-time ingestion of smart grid data into a platform that can forecast those disruptions that invoke the system's self-healing function within the smart grid's 2-4 second decision loop.

### SUMMARY OF THE INVENTION

A general object of the invention is to provide a system and method detecting or predicting a power grid disruption. The invention provides coupling of multiple real-time data streams (e.g., 1-2 TB per hour) into dynamic models. These models identify predicted disruptions in time (e.g., 2-4 seconds) to trigger the smart grid's self-healing functions. The method, software, and computer system of this invention include events-detection algorithms that can scale with the size of data, algorithms that can not only handle the multi-dimensional nature of the data, but also model both spatial and temporal dependencies in the data, which, for the most part, are highly nonlinear, and algorithms that can operate in an online fashion with streaming data.

The general object of the invention can be attained, at least in part, through a method of detecting a power grid disruption. The method includes receiving a stream of data about a power grid, converting the stream of data into a univariate time sequence, extracting a power event from the univariate time sequence, and predicting the power grid disruption from the extracted power event.

The invention further includes a method of detecting a power grid disruption that includes receiving with a data processor a stream of data about a power grid, automatically detecting an anomaly in the data, automatically comparing the anomaly to a database of power disruption contingencies, and predicting the power grid disruption upon matching the anomaly to one of the power disruption contingencies.

The invention includes anomaly detection techniques that take into account spatial, temporal, multi-dimensional aspects of the received grid data set. The invention converts a multi-dimensional grid data sequence into a univariate time series that captures the changes between successive windows extracted from the original sequence, such as by using singular value decomposition (SVD), and then applies anomaly detection techniques for univariate time series. The invention provides algorithms scalable to huge datasets by adopting techniques from perturbation theory, incremental SVD analysis.

The method of this invention is implemented by a data processor executing coded instructions stored on a recordable medium. The data processor, which is a computer apparatus, is used to execute a series of commands of the instruction that represent the method steps described herein. The data processor or computer may be a mainframe, a super computer, a PC or Apple Mac personal computer, a hand-held device, or a central processing unit known in the art.

The data processor or computer is programmed with a series of instructions that, when executed, cause the data processor or computer to perform the method steps as described and claimed herein. In one embodiment, the invention includes a series of preprogrammed instructions on a recordable medium that, when executed by a computing machine, cause the computing machine to predict a power grid disruption. The steps include receiving streams of data about a power grid from a plurality of remote power grid sensors, converting the streams of data into a univariate time sequence, identifying an anomaly in the univariate time sequence, and predicting the power grid disruption from the identified anomaly.

The instructions that are performed are stored on a non-transitory data storage device. The machine-readable data storage device can be a portable memory device that is readable by the data processor or computer apparatus. Such portable memory device can be a compact disk (CD), digital video disk (DVD), a Flash Drive, any other disk readable by a disk driver embedded or externally connected to a computer, a memory stick, or any other portable storage medium currently available or yet to be invented. Alternately, the machine-readable data storage device can be an embedded component of a computer such as a hard disk or a flash drive of a computer.

The computer and machine-readable data storage device can be a standalone device or a device that is imbedded into a machine or system that uses the instructions for a useful result.

Other objects and advantages will be apparent to those skilled in the art from the following detailed description taken in conjunction with the appended claims and drawings.

### BRIEF DESCRIPTION OF THE DRAWINGS

FIG. 1 representatively illustrates exemplary system components according to one embodiment of this invention.

FIG. 2 is a flow diagram illustrating steps according to one embodiment of this invention.

### DETAILED DESCRIPTION OF THE INVENTION

The present invention includes a computer-implemented method, and software for executing the method, for monitoring the electric grid and identifying issues and/or predicting failures.

The invention includes a computer system in communication with an electric power grid to receive and analyze information about the grid.

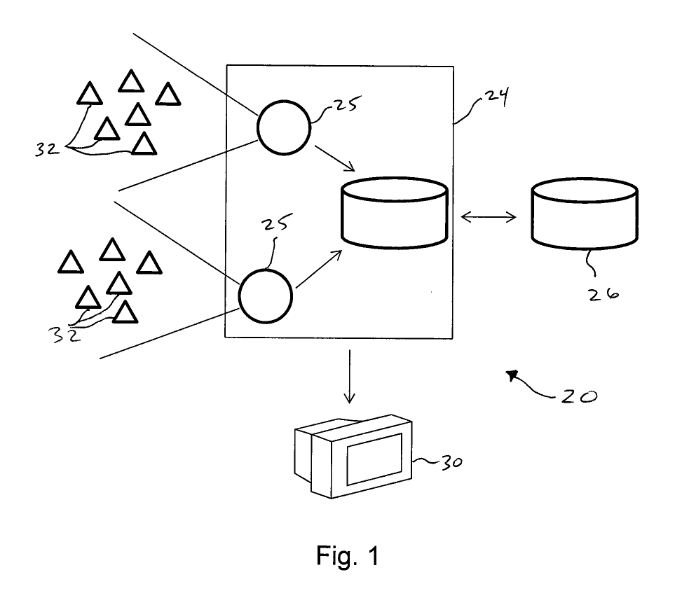

FIG. 1 representatively shows a system 20 according to one embodiment of this invention. A plurality of sensors 32 are in sensing combination with the electric grid at various remote positions. The sensors desirable continually monitor and/or measure one or more properties of the electric grid, such as, without limitation, frequency, voltage, or phase angle. In one embodiment, the sensors are a frequency measurement system designed to provide real-time measurements of frequency transients in the electric power system. Various numbers and types of sensors can be used, depending on need. In one embodiment within the scope of this invention, the sensors desirably have the characteristics of a) cyber-security using hardware-accelerated cryptography, b) producing a symbol rate of 8000 measurements per second, c) providing at that rate, average frequency with a sensitivity of 25 mHz within 80 ms, and d) employing a timing system that can accurately time-stamp each measurement using VLF broadcast time-code signals and the IEEE 1588 precision time protocol standard.

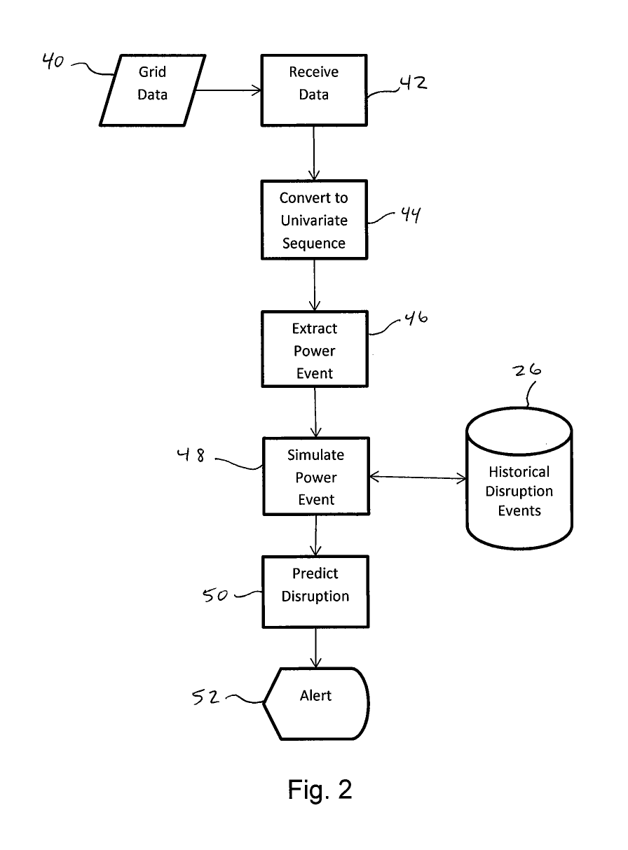

Each of the sensors 32 provides a stream of data about the power grid. Referring to FIG. 2, the data 40 is streamed to a receiving computing system in step 42, such as data processing system 24 of FIG. 1. This data stream provides wide area data for significant grid disruption events. It is expected that for a nation-wide capability, between 1 and 2 TB of data can be collected per hour. It is desirable to have the data sequences combined instead of separately analyzing the data, as a separate analysis may, for example, confuse and/or mask the event of a remote disruption having an effect across many areas of the grid. System 24 receives the data streams, such as using one or more concentration clusters 25, and combines the data streams into one or more concentrated streams. In step 44 of FIG. 2, the system 24 converts the multi-dimensional sequences of data into a univariate time sequence, such as by using singular value decomposition (SVD). The univariate time sequence includes the changes between successive windows extracted from the original sequence.

In step 46, the system extracts a power event from the univariate time sequence. The power event represents a fluctuation or anomaly in the data collected by the sensors. For example, the extracted power event can be a predetermined change in one of frequency, voltage, or phase angle within the univariate time sequence. The power event, most likely an anomaly pattern, can be extracted or otherwise determined by applying anomaly detection techniques to the univariate time sequence. One suitable anomaly detection algorithm of this invention is referred to as the GPU Accelerated Event Detection Algorithm (GAEDA). The GAEDA code (e.g., DOE Package ID 002748MLTPL00) is a new online anomaly detection technique that takes into account spatial, temporal, multi-dimensional aspects of the data set. In one embodiment, the GAEDA algorithm is faster by using efficient mapping to hardware accelerators such as Graphic Processing Units (GPU). The algorithm maximizes data parallelism and explicitly manages the data cache. With efficient data streaming techniques, the algorithm can get the data onto and off of the GPU in shorter times than the conventional processes. The algorithm can identify frequency excursion events within the first 1-2 seconds using a sliding window approach simultaneously with smoothing to minimize noise that would mask the early signals present in the first 1-2 seconds. In one embodiment, the algorithm is made scalable to big datasets by adopting techniques from perturbation theory for incremental SVD analysis. Tensor decomposition techniques which reduce computational complexity can be used to monitor the change between successive windows and detect anomalies. For change detection Gaussian Process (GP) models which account for nonlinear dependencies in the data can be incorporated.

The system then predicts the power grid disruption from the extracted power event. The prediction desirably includes a size and location of the power grid disruption. System 24 includes or is in communication with a database 26 of recorded power event disruption contingencies. In step 48, the pattern of the extracted power event of step 46, such as the frequency change and duration, is searched within the database 26 of recorded disruption events to find a recorded disruption event having a matching anomaly pattern. In step 50, the matching recorded disruption event is used to predict the power grid disruption resulting from the power event anomaly. In step 52, the system automatically sends an alert with information on the predicted power grid disruption to the appropriate party, such as the power company control system 30 in FIG. 1.

The present invention is described in further detail in connection with the following example(s) which illustrates or simulates various aspects involved in the practice of the invention. It is to be understood that all changes that come within the spirit of the invention are desired to be protected and thus the invention is not to be construed as limited by these examples.

A database system to receive the real-time data from frequency sensor system was developed. In excess of 50 frequency recording units were porting real-time data to the Oak Ridge National Laboratory. A documented data set collected in July 2009, which illustrated the coupled nature of the Eastern Interconnect within the frequency data, was used as test data. Within this data set, there was unique, archived data to illustrate the expanded, coupled nature of smart grid control. This stream provided a real-time test stream where the data structure, speed, accuracy, latency, and signature potential could be assessed on live nation-wide data.

This test data set was unique and captured wide area data for significant grid disruption events. It was expected that between 1 and 2 TB of data will be collected per hour for a nation-wide capability, and at least one year of data should be archived for both research and forensics. The database structure delivered this data automatically to the anomaly identification algorithms while still trapping data errors, inconsistencies, and data gaps.

The total database size might reach 10 petabytes for active interrogation according to this invention. The first inclination was to parse the data and solvers to separate processors. However, if the cause of the disruption is remote and creates anomalies throughout the grid, then this parallelization would mask the signature extraction. The database desirably is structured to handle this coupling of the data. The prototype database and key data structure included a dataset of two months of real FNET datasets for June and July 2009 from several FDR devices mostly within the Eastern Interconnection. The given data sets were then duplicated and white noise or a known signal added as explained in the following:
Let X₁ and X₂ represent the actual data sets for June and July 2009 respectively;
Replicate X₁ and X₂, N number of times each, where N is the limit when the size of the datasets is at least 0.25 TB; generate four sets of replication, each of size at least 0.2 TB; the total size of data generated equals at least 1 TB.
Let Y₁, Y₂, . . . , Y_{N} represent the first set of new data sets defined as:
Yᵢ=X₁+SNRᵢ, i=1, . . . , N, where SNR in dB=−10,−8, −6, −4, . . . .
SNR (signal-to-noise ratio)=20 log 10 normX1 normnoise . . . .
Let Z₁, Z₂, . . . , Z_{N} represent the second set of new data sets defined as:
Zᵢ=X₂+SNRᵢ, i=1, . . . , N, where SNR in dB=−10, −8, −6, −4, . . . .
SNR (signal-to-noise ratio)=20 log 10 noremX1 normnoise.
Let W₁, W₂, . . . , W_{N} represent the third set of new data sets defined as:
Wᵢ=X₁+Pᵢ, i=1, . . . , N, where P is either a non-linear, stationary; linear, non-stationary; non-linear non-stationary signal. Different signals in each category were randomly selected from a library of signals.
Let R₁, R₂, . . . , R_{N} represent the fourth set of new data sets defined as: Rᵢ=X₂+Pᵢ, i=1, . . . , N, where P is either a non-linear, stationary; linear, non-stationary; non-linear non-stationary signal. Different signals in each category are randomly selected from a library of signals. Rᵢ=X₂+Pᵢ, i=1, . . . , N, where P is either a non-linear, stationary; linear, non-stationary; non-linear non-stationary signal. Different signals in each category were randomly selected from a library of signals.
   Using the generated data sets and the actual data sets, the expected performance of methods in the next step were summarized as follows:
1. The methods should detect the same events in (or perform the same way using) X₁, Yᵢ, and Wᵢ and the computation time should be about the same.
2. The methods should detect the same events in (or perform the same way using) X₂, Zᵢ, and Rᵢ and the computation time should be about the same.
   Using the database structure developed above, the data set was interfaced with fast signature recognition algorithms to identify the anomaly disruptions or impending failures within the grid. These anomaly signatures are necessarily more complex as more reactive elements are added to the grid. The starting point was with signatures based on the shape of the frequency variation and the time that the disruption is detected in multiple sensors. This disruption data then was aggregated into a loss of component, node, or edge as input data to one or more national scale dynamic models that would then create a forecast or suite of forecasts within the 2-4 second decision loop.

As noted above, a new algorithmic approach, as well as a parallel formulation, was needed to address this anomaly detection in the data. The state-of-the-art algorithms were not well suited to handle the demands of streaming data analysis. There was a need for an events detection algorithm that could scale with the size of data, which could not only handle multi-dimensional nature of the data, but also model both spatial and temporal dependencies in the data, which, for the most part, were highly nonlinear, and that could operate in an online fashion with streaming data. The basic idea behind the approach was to (a) to convert the multi-dimensional sequence into a univariate time series that captured the changes between successive windows extracted from the original sequence using singular value decomposition (SVD), and then (b) to apply known anomaly detection techniques for univariate time series. A key challenge for the proposed approach was to make the algorithm scalable to big datasets by adopting techniques from perturbation theory for incremental SVD analysis. Recent advances in tensor decomposition techniques were used, which reduced computational complexity to monitor the change between successive windows and detect anomalies in the same manner as described above. For change detection, Gaussian Process (GP) models which account for nonlinear dependencies in the data were used.

The rare event and GP based online change detection algorithms were computationally expensive. For example, hyper-parameter estimation of GP was O(n3). Therefore parallel solutions on many core processing systems were used, because the algorithms involved many numerical operations and were highly data-parallelizable.

Obtaining real-time situational awareness presented a diverse set of computational requirements. These requirements could be categorized into three major goals. First, in real-time, process incoming data from distributed sensors (estimated at 2 TB/hour) and provide actionable intelligence to grid operators in a two to four second decision loop. Second, the processing includes two phases: processing sensor data and searching through the scenario library. Third, the scenario library providing metrics including the approximate location of events, event type, and trip amount (MW loss).

A large number of simulations were executed to obtain frequency signatures for events representing each (n−k) contingency. These signatures were collected, analyzed for significance, and stored in memory for fast searches while maintaining a high availability archive of one year of sensor data (estimated at 8.76 PB) for batch analysis.

During the course of the study, an integrated prototype solution was developed and demonstrated using a mix of High Performance Computing (HPC) technologies. Real-time event detection was accomplished through the development of the GAEDA (GPU-Accelerated Event Detection Algorithm) software. GAEDA leveraged the high bandwidth of graphics processing units (GPUs), with each NVIDIA Tesla M2070 GPU capable of processing 1.2 GB/s of frequency data. The signature (scenario library) database search was also accelerated using GPUs, attaining a rate of 1.5 million signatures per second per GPU.

The disruption signatures were generated using Oak Ridge National Laboratory's (ORNL) “Toolkit for Hybrid Modeling of Electric power systems” (THYME) operating on ORNL's Keeneland cluster, which is a 200 Teraflop high performance computer, for all (n−1) contingencies in the Eastern interconnect, resulting in a total of 58,789 simulations. To support this large number of simulations, Keeneland was leveraged, the NSF Track2D experimental HPC system. Keeneland consists of 120 nodes, each with a dual socket Intel Westmere CPU and an NVIDIA M2090 GPU. Analysis indicated that 1317/58789 cases (2.24%) exhibit frequency depression exceeding 8 mHz. Because 8 mHz represented the sensors' limit of detection as established, this represented a greater than 40 times faster searching capability when undetectable events are purged from the scenario library.

A design was also constructed for the archive of one year of sensor data. Utilizing compression, total data size was reduced from roughly 8.76 PB to 7.01 PB, a twenty percent reduction. Due to the batch nature of analysis on this data, a large-scale Hadoop cluster was ideal. At a minimum, this cluster would require an estimated 220 nodes, each with 16 2 TB hard drives (which drive the overall cost of the system).

Summary Table

| Task | Requirement | Prototype Solution |
|---|---|---|
| Event Detection | Process 2TB/hr sensor | GAEDA, 1.2 GB/s |
| | data in real-time | |
| Signature Search | Search all simulated | GAEDA, 1.5 MM sig/s |
| | scenarios in 2000 ms | |
| Scenario Library | Exponential number of | THYME on Keeneland, |
| | PG simulations | 58k simulations |
| Sensor Data | Store 7.01 PB data | 220 Node Hadoop Cluster |
| Archive | | |

One critical problem requiring high performance computing (HPC) was real-time power grid monitoring of large scale disruptions and look-ahead forecast of future states. A fast detection method was developed for large scale power grid disruptions within the smart grid's 2-4 second decision loop. The method uses GPU accelerated algorithms to detect events based on an array of inexpensive frequency detectors that detect excursions resulting from a loss of one or more components such as generators, transmission lines, and transformers. A library of contingencies with the corresponding extracted signatures at the 50,000 buses of the Eastern Interconnection (EI) was generated with a 200 Teraflop computational platform that generated 50 million records to match against the measured signature. Only the sensor-detectable records (contingencies) were considered for the library instead of all possible scenarios, to incredibly reduce the search and detection times. The criterion of being able to detect a 200 MW disruption within 1000 msec was used, and leaving the rest of the time for transport of the measured frequency excursions (signatures). The power flow analyses on the EI showed that a 25 MW disruption approximately generates about 1 mHz frequency excursion. Therefore, those records that showed a frequency excursion of less than 8 mHz were considered as undetectable and thus eliminated. Fast searching of the library to present potential component losses and future states demonstrated the ability to search 3 million contingencies within the design requirement of 1000 msec. This placed a practical limit of N−10 contingencies for an EI sized grid.

To generate the contingency scenarios, time domain simulations were performed using the THYME simulator operating on ORNL's Keeneland cluster. The Summary Table above provides the detected power grid components' statuses and assessed the alerts to the power system operators via an interactive overlay within a web-based Google Earth geographic platform. Numerical results are presented to demonstrate the accuracy and detection speed of the proposed approach.

The simulation results from the THYME simulator were interfaced with different visualization frameworks (Google Earth platform and Tableau Software) to provide an understanding of the frequency variations over space and time for different contingency scenarios and useful insights into these datasets. Being able to port these big data results directly into commercial visualization tools like Tableau, STI (Space-Time-Insight) by displaying statuses/alerts and making them available directly on the commander's tablet and the control room has proved to be extremely helpful in presenting these results to decision makers. These visualizations display the results in a highly intuitive way by representing several parameter values with different visual attributes (color, size, height etc.) simultaneously.

For GridLab-D, which is a power distribution system simulation and analysis tools, a VERDE (Google Earth platform) framework was developed to study the voltage fluctuations, effect of electric vehicle (EV) adoption on the distribution grid and to provide real time situational awareness due to weather events. Here one of the 24 generic Feeder models (R5_{—}12.47 kv) which represented a moderately populated suburban area was geo-located over a Knoxville, Tenn. neighborhood and the simulations results were displayed as a time animation for a 12 hour period. Typically there are voltage drops at the end of the feeder line away from the substation creating an under-voltage condition. Such patterns can be easily identified in these heat map animations. These visualizations were developed to the power system operators in their control room almost real-time for decision-making process.

Thus the invention provides a computer-implemented method, and the corresponding software, for predicting power disruptions. The method of the this invention allows for the combination of large amounts of streaming grid data, and the quick analysis of the data to extract and identify anomaly patterns for use in predicting power disruptions.

While there has been shown and described what are at present considered the preferred embodiments of the invention, it will be obvious to those skilled in the art that various changes and modifications can be prepared therein without departing from the scope of the inventions defined by the appended claims.

What is claimed is:

1. A method of detecting a power grid disruption, the method comprising:
receiving a stream of data about a power grid;
converting the stream of data into a univariate time sequence;
extracting a power event from the univariate time sequence; and
predicting the power grid disruption from the extracted power event.

2. The method of claim 1, wherein a data processor receives the stream of data and includes a recordable medium comprising executable coded instructions that when executed causes the data processor to perform the converting, detecting, and predicting steps.

3. The method of claim 1, wherein the univariate time sequence includes changes between successive windows extracted from an original sequence.

4. The method of claim 1, wherein the stream of data is received from a plurality of remote sensors in sensing combination with the power grid.

5. The method of claim 1, wherein extracting power events comprises anomaly detection.

6. The method of claim 1, wherein the extracted power event is selected from a predetermined change in one of frequency, voltage, or phase angle within the univariate time sequence.

7. The method of claim 1, wherein the prediction includes a size and location of the power grid disruption.

8. The method of claim 1, further comprising:
a data processor comparing the extracted power event to a database of recorded disruption events; and
the data processor matching the extracted power event to one recorded event of the database to predict the power grid disruption.

9. The method of claim 1, further comprising comparing anomaly patterns of the extracted power event to patterns of the recorded disruption events.

10. The method of claim 1, further comprising automatically sending an alert with information on the predicted power grid disruption.

11. A method of detecting a power grid disruption, the method comprising:
receiving with a data processor a stream of data about a power grid;
automatically detecting an anomaly in the data;
automatically comparing the anomaly to a database of power disruption contingencies; and
predicting the power grid disruption upon matching the anomaly to one of the power disruption contingencies.

12. The method of claim 11, wherein the anomaly is selected from a predetermined change in one of frequency, voltage, or phase angle within the data.

13. The method of claim 11, wherein the prediction includes a size and location of the power grid disruption.

14. The method of claim 11, further comprising automatically sending an alert with information on the predicted power grid disruption.

15. The method of claim 11, further comprising:
receiving with the data processor a plurality of continuous streams of data about the power grid from a plurality of remote power grid sensors; and
the data processor automatically converting the plurality of continuous streams into a univariate time sequence.

16. The method of claim 15, wherein the anomaly is selected from a predetermined change in one of frequency, voltage, or phase angle within the univariate time sequence.

17. A series of preprogrammed instructions on a non-transitory recordable medium that, when executed by a computing machine, cause the computing machine to predict a power grid disruption, the steps comprising:
receiving streams of data about a power grid from a plurality of remote power grid sensors;
converting the streams of data into a univariate time sequence;
identifying an anomaly in the univariate time sequence; and
predicting the power grid disruption from the identified anomaly.

18. The instructions of claim 17, further comprising detecting a predetermined change in one of frequency, voltage, or phase angle within the univariate time sequence.

19. The instructions of claim 18, further comprising comparing the predetermined change to a plurality of change patterns in a database of power disruption contingencies.

20. The instructions of claim 19, wherein the predetermined change comprises an anomaly pattern.
